(19) United States
(12) Patent Application Publication
(10) Pub. No.: US 2013/0207140 A1
(43) Pub. Date: Aug. 15, 2013

(54) Semiconductor Optical Element Semiconductor Optical Module and Manufacturing Method Thereof

(71) Applicant: Hitachi, Ltd., (US)

(72) Inventors: Shigeki MAKINO, Tsuchiura (JP); Takeshi KITATANI, Hino (JP); Kazunori SHINODA, Musashino (JP); Koichiro ADACHI, Musashino (JP)

(73) Assignee: Hitachi, Ltd., Tokyo (JP)

(21) Appl. No.: 13/741,858

(22) Filed: Jan. 15, 2013

(30) Foreign Application Priority Data
Feb. 13, 2012 (JP) 2012-027973

(51) Int. Cl. H01L 33/58

(52) U.S. Cl. CPC H01L 33/58
USPC 257/94; 438/31

(57) ABSTRACT

A semiconductor optical element comprises a substrate, an active layer lying in one direction over the substrate from which light exits using a side in the shorter direction among the four sides as an outgoing end, a buried layer provided over the substrate and covering two sides in the longitudinal direction among the four sides, a clad layer provided over the active layer and over the substrate existing on the extension line of the outgoing end of the active layer, a mirror which reflects light from the active layer provided on the extension line of the active layer, wherein the mirror is formed in the clad layer.

### CLAIM OF PRIORITY

The present application claims priority from Japanese application JP 2012-027973 filed on Feb. 13, 2012, the content of which is hereby incorporated by reference into this application.

### FIELD OF INVENTION

The present invention relates to a semiconductor optical element, an optical module employing it, and a manufacturing method thereof. In particular, it relates to a semiconductor optical element typified by a semiconductor laser and a photodiode.

### BACKGROUND OF THE INVENTION

With increasing rapid proliferation of broadband networks, in order to process large-volume data without delay, introduction of optical communication systems has been considered not only for long distances of several kilometers or more, such as a main network, metro, and access system, etc. but also for short distances in between transmission devices (from several meters to several hundreds of meter) or in a device (from several centimeters to several tens of centimeter). Against this background, speed-up, downsize, and energy-saving of an optical communication module become important challenges.

High-speed and high-power operation at high temperatures, high-efficiency optical coupling with an optical fiber, and space-saving and low-cost mounting, etc. are strongly required for a light source device of such an optical module. This invention delivers a low-cost semiconductor optical element suitable for the above-mentioned high-speed, small size, and low power consumption optical module.

As a preferable light source device to achieve speed-up, downsizing, and energy-saving of an optical communication module, an optical element is proposed wherein a resonator is constructed in the in-plane direction of the substrate and a mirror is arranged at the position where the main outgoing beam of the resonator enters, or wherein only a part of resonator is constructed in the in-plane direction of the substrate and a mirror is arranged in the resonator over the above-mentioned substrate. Moreover, a structure is proposed in which coupling efficiency to an optical fiber is improved by an accumulating lens in the aforementioned optical element and a focusing of the signal light therein.

The laser, which outputs the main signal light in the surface direction of the substrate by using the mirror, has advantages such as high-power operation at high temperatures, high-speed operation, and reduction of optical coupling loss by lens accumulation, etc. And, excellent operation such as 25 Gbps at 85° C. was reported in recent years.

In general, for energy-savings in a semiconductor laser, a so-called buried hetero (BH: Buried-Hetero) structure is effective in which an active layer is buried with a semi-insulating semiconductor. For instance, in the laser using InP as a substrate which is a typical material of the semiconductor laser, semi-insulating (SI: Semi Insulating) InP in which iron (Fe) etc. is doped is used as a buried layer. The leakage current which does not contribute to luminescence can be decreased by burying a laser active layer with high-resistance SI-InP, and low current operation becomes possible.

In FIG. 7 of Japanese Unexamined patent Application Publication No. 2008-277445, a manufacturing method is disclosed to make the laser a BH structure which outputs the main signal light in the direction of the surface of the substrate surface by the mirror formed in the buried layer. According to the procedure disclosed in Japanese Unexamined Patent Application Publication No. 2008-277445 (specifically in FIG. 7), a laser having the BH type structure can be processed in which the main signal light is output in the direction of the substrate surface by the mirror.

### SUMMARY OF THE INVENTION

However, in the prior art disclosed as above, it is understood that forming an excellent mirror is difficult in the BH structure, and the yield of the characteristics such as optical coupling efficiency decreases. It is because flatness of the region where the mirror should be formed is deteriorated during selective growth of semi-insulating InP buried layer 16 shown in FIG. 7 of Japanese Unexamined Patent Application Publication No. 2008-277445.

Because the raw material of the buried layer supplied over the dielectric mask 110 during selective growth does not stay over the mask but diffuses to the crystal exposure region neighborhood of the mask, the amount of supply of the raw material in the vicinity of the mask increases substantially, resulting in increasing the growth rate compared with that away from the mask. The effect of the growth rate enhancement of this buried layer is more remarkable near the mask and gradually decreases with distance from the mask, and almost no effect remains when the distance becomes the migration length of the raw material (several tens of microns or less) or more. Thus, because the crystal growth rate is different depending on the distance from the mask, an inclination is formed over the crystal surface of the buried layer several tens of microns from the vicinity of the mask.

When the crystal surface of the region where the mirror is formed is inclined as above-mentioned, it is difficult to form a smooth mirror without misalignment with good yield. The misalignment of the mirror greatly influences the outgoing angle of the signal light, and loss occurs in a mirror having low smoothness when light is reflected. Moreover, if a mirror is formed far enough from the tip of the mesa to avoid the inclined region, transmitted radiation expands inside the semiconductor and cannot be reflected by the mirror because there is no confinement structure of light between the tip of the mesa and the mirror.

For instance, a composition described in the claims is adopted to solve the above-mentioned problems. The present invention includes a plurality of means to solve the above-mentioned topics. One example is that a semiconductor optical element including a substrate, an active layer laying in one direction over the substrate from which light exits using a side in the shorter direction among the four sides as an outgoing end, a buried layer provided over the substrate and covering the two sides in the longitudinal direction among the four sides, a clad layer provided over the active layer and over the substrate existing on the extension line of the outgoing end of the active layer, and a mirror, which reflects light from the active layer, provided on the extension line of the active layer, in which the aforementioned mirror is formed in the clad layer.

Or, a semiconductor optical element including a semiconductor substrate, a core layer and a clad layer formed over a substrate, a wave guide laying in one direction wherein light enters and exits from a side in the shorter direction among the four sides as an outgoing edge face, a mirror formed at the position which reflects light from the wave guide on the extension line of the wave guide, and a buried layer formed over the substrate and covering at least two sides in the longitudinal direction among the four sides of the wave guide, in which the clad layer is further formed over the semiconductor substrate on the extension line of the incident and outgoing end of the wave guide and the mirror is formed in the clad layer.

Or, a manufacturing method of a semiconductor optical element including, a first process forming a clad layer over an active layer, which is formed over a semiconductor substrate and has four sides, and over the above-mentioned semiconductor substrate, a second process forming a mask pattern over the clad layer; a third process etching the clad layer by using the mask pattern, a fourth process forming a buried layer over the semiconductor substrate surrounding the clad layer, and a fifth process forming a mirror at a position where light exiting from the active layer is reflected, in which the mask pattern is constructed of a wave guide region pattern formed over the active layer and a mirror region pattern to keep a region for forming the mirror.

The present invention allows manufacturing a semiconductor optical element with good yield.

### BRIEF DESCRIPTION OF THE DRAWINGS

FIG. 1A is a perspective drawing (partially transparent) of an integrated and buried diagonal mirror/lens DFB laser according to a first embodiment of the invention;

FIG. 1B is a B cross-sectional drawing of an integrated and buried diagonal mirror/lens DFB laser according to the first embodiment of the invention;

FIG. 1C is a C cross-sectional drawing of an integrated and buried diagonal mirror/lens DFB laser according to the first embodiment of the invention;

FIG. 2A is a cross-sectional drawing illustrating a manufacturing method of an integrated and buried diagonal mirror/lens DFB laser according to the first embodiment of the invention;

FIG. 2B is a cross-sectional drawing illustrating a manufacturing method of an integrated and buried diagonal mirror/lens DFB laser according to the first embodiment of the invention;

FIG. 2C is a cross-sectional drawing illustrating a manufacturing method of an integrated and buried diagonal mirror/lens DFB laser according to the first embodiment of the invention;

FIG. 2D is a cross-sectional drawing illustrating a manufacturing method of an integrated and buried diagonal mirror/lens DFB laser according to the first embodiment of the invention;

FIG. 2E is a top drawing of a mask pattern illustrating the manufacturing method of an integrated and buried diagonal mirror/lens DFB laser according to the first embodiment of the invention;

FIG. 2F is a cross-sectional drawing illustrating a manufacturing method of an integrated and buried diagonal mirror/lens DFB laser according to the first embodiment of the invention;

FIG. 2G is a cross-sectional drawing illustrating a manufacturing method of an integrated and buried diagonal mirror/lens DFB laser according to the first embodiment of the invention;

FIG. 2H is a cross-sectional drawing illustrating a manufacturing method of an integrated and buried diagonal mirror/lens DFB laser according to the first embodiment of the invention;

FIG. 3A is a perspective drawing (partially transparent) of an integrated and buried diagonal mirror/lens DFB laser according to a second embodiment of the invention;

FIG. 3B is a B cross-sectional drawing of an integrated and buried diagonal mirror/lens DFB laser according to the second embodiment of the invention;

FIG. 4A is a drawing illustrating a manufacturing method of an integrated and buried diagonal mirror/lens DFB laser according to the second embodiment of the invention;

FIG. 4B is a drawing illustrating a manufacturing method of an integrated and buried diagonal mirror/lens DFB laser according to the second embodiment of the invention;

FIG. 4B is a top drawing of a mask pattern in a manufacturing method of an integrated and buried diagonal mirror/lens DFB laser according to the second embodiment of the invention;

FIG. 5A is a perspective drawing (partially transparent) of an integrated and buried diagonal mirror/lens DFB laser according to a third embodiment of the invention;

FIG. 5B is a B cross-sectional drawing of an integrated and buried diagonal mirror/lens DFB laser according to the third embodiment of the invention;

FIG. 5C is a C cross-sectional drawing of an integrated and buried diagonal mirror/lens DFB laser according to the third embodiment of the invention;

FIG. 6A is a drawing illustrating a manufacturing method of an integrated and buried diagonal mirror/lens DFB laser according to the third embodiment of the invention;

FIG. 6B is a drawing illustrating a manufacturing method of an integrated and buried diagonal mirror/lens DFB laser according to the third embodiment of the invention;

FIG. 6C is a drawing illustrating a manufacturing method of an integrated and buried diagonal mirror/lens DFB laser according to the third embodiment of the invention;

FIG. 6D is a drawing illustrating a manufacturing method of an integrated and buried diagonal mirror/lens DFB laser according to the third embodiment of the invention;

FIG. 6E is a drawing illustrating a manufacturing method of an integrated and buried diagonal mirror/lens DFB laser according to the third embodiment of the invention;

FIG. 7 is a perspective schematic drawing of an integrated and buried diagonal mirror/lens DFB laser array according to a fourth embodiment of the invention;

FIG. 8A is a perspective drawing (partially transparent) of an integrated and buried diagonal mirror/lens DFB laser according to a fifth embodiment of the invention;

FIG. 8B is a B cross-sectional drawing of an integrated and buried diagonal mirror/lens EA/DFB laser according to the fifth embodiment of the invention;

FIG. 8C is a C cross-sectional drawing of an integrated and buried diagonal mirror/lens EA/DFB laser according to the fifth embodiment of the invention;

FIG. 9A is a drawing illustrating a manufacturing method of an integrated and buried diagonal mirror/lens EA/DFB laser according to the fifth embodiment of the invention;

FIG. 9B is a drawing illustrating a manufacturing method of an integrated and buried diagonal mirror/lens EA/DFB laser according to the fifth embodiment of the invention;

FIG. 9C is a drawing illustrating a manufacturing method of an integrated and buried diagonal mirror/lens EA/DFB laser according to the fifth embodiment of the invention;

FIG. 9D is a drawing illustrating a manufacturing method of an integrated and buried diagonal mirror/lens EA/DFB laser according to the fifth embodiment of the invention;

FIG. 9E is a drawing illustrating a manufacturing method of an integrated and buried diagonal mirror/lens EA/DFB laser according to the fifth embodiment of the invention;

FIG. 9F is a drawing illustrating a manufacturing method of an integrated and buried diagonal mirror/lens EA/DFB laser according to the fifth embodiment of the invention;

FIG. 9G is a drawing illustrating a manufacturing method of an integrated and buried diagonal mirror/lens EA/DFB laser according to the fifth embodiment of the invention;

FIG. 9H is a drawing illustrating a manufacturing method of an integrated and buried diagonal mirror/lens EA/DFB laser according to the fifth embodiment of the invention;

FIG. 9I is a drawing illustrating a manufacturing method of an integrated and buried diagonal mirror/lens EA/DFB laser according to the fifth embodiment of the invention;

FIG. 9J is a drawing illustrating a manufacturing method of an integrated and buried diagonal mirror/lens EA/DFB laser according to the fifth embodiment of the invention; and

FIG. 10 is a cross-sectional drawing of an optical module illustrating the sixth embodiment of the invention.

### DETAILED DESCRIPTION OF THE PREFERRED EMBODIMENTS

Hereafter, the preferred embodiments of the invention will be described using the first to sixth embodiments in reference to the accompanying drawings.

### First Embodiment

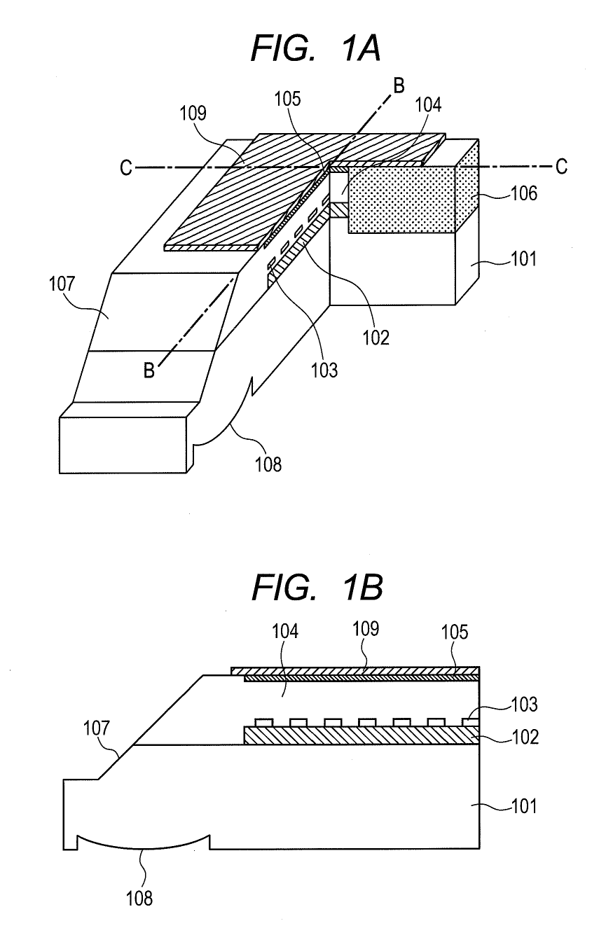

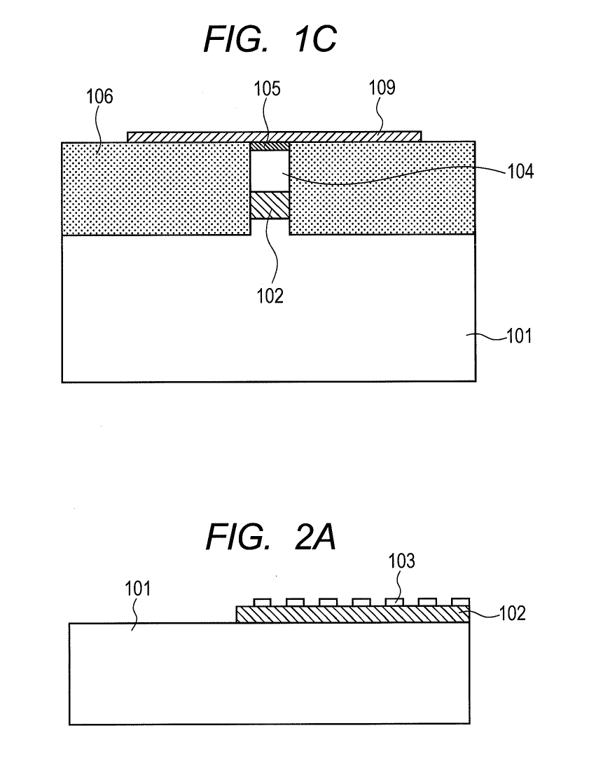

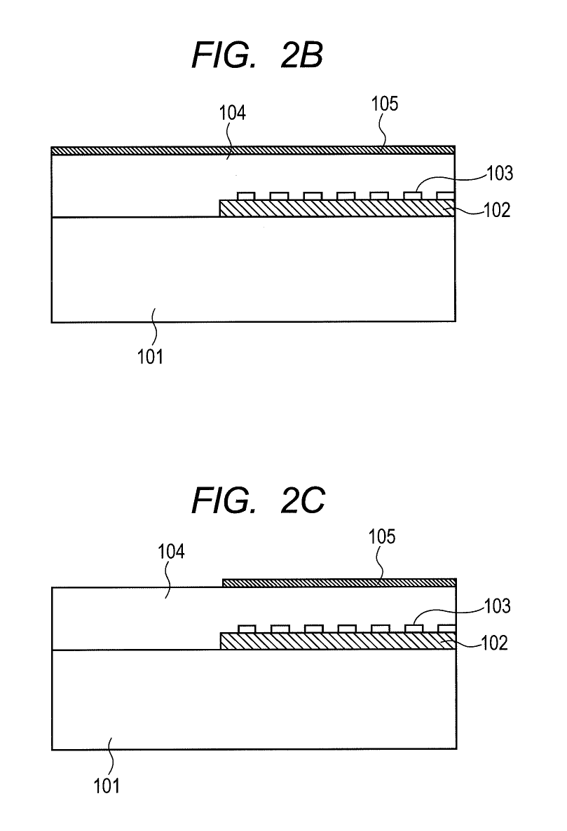

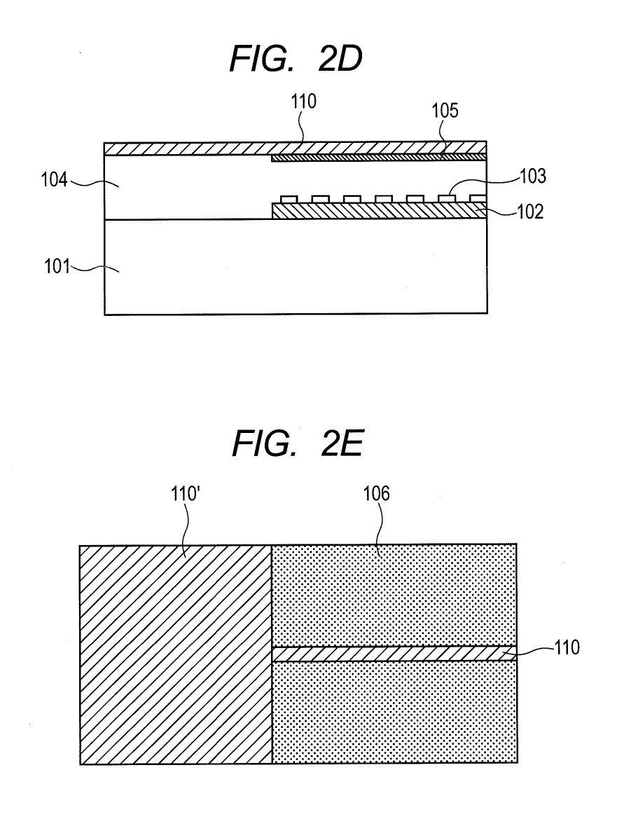

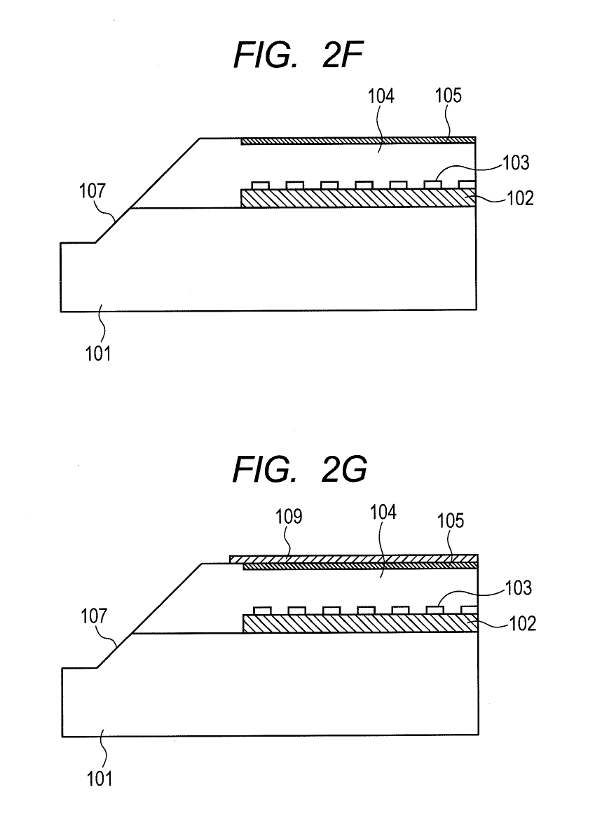

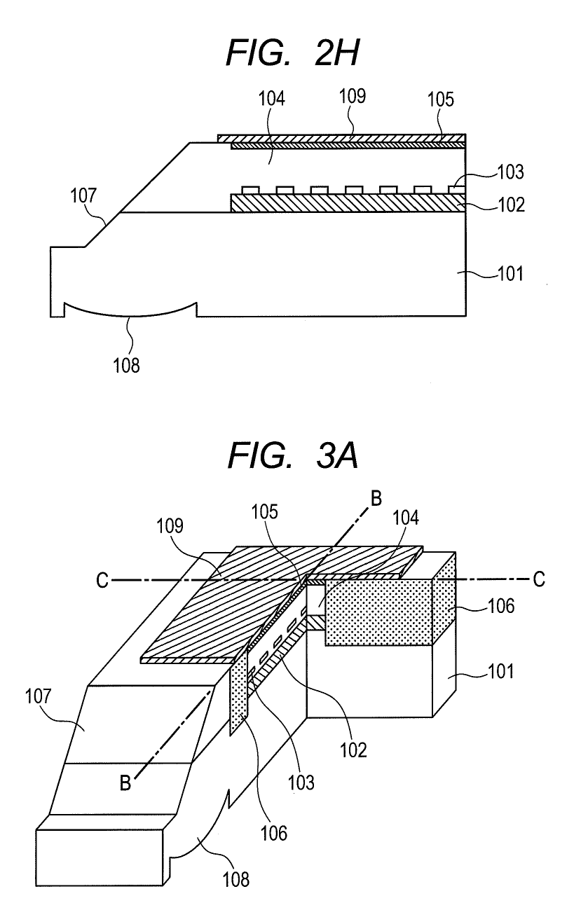

An embodiment of a semiconductor optical element according to the present invention will be described using FIGS. 1 and 2. However, the figures only explain this embodiment, and neither the size of the figures nor the reduced scale described in this embodiment is always necessarily corresponding. Moreover, detailed descriptions such as a minute step and structure which have no influence on the technology disclosed in the invention are omitted.

Firstly, crystal growth of an active layer 102 and a diffraction grating supply layer 103′ is carried out over an n-type InP substrate 101 by using a Metal-organic Vapor Phase Epitaxy (MOVPE) etc. As the active layer, a multiple quantum well etc. is preferable in which, for instance, a pair of quantum wells consisting of an InGaAlAs mixed crystal and barrier layer are multiply stacked. Light can be efficiently confined when a semiconductor clad layer, which has a refractive index higher than InP and lower than the average refractive index in the multiple quantum well, is provided to be several tens of nanometer over and below the active layer.

Moreover, the diffraction grating supply layer 103′ is provided to form a Distributed Feedback (DFB) between the active layer and the clad layer, or in the clad layer. The thickness of the semiconductor multilayer structure consisting of these is about 200 nm to 300 nm. According to the means such as interference exposure and electron beam exposure, etc., a resist pattern having a desired pitch is formed over the diffraction grating supply layer 103′ and unnecessary parts are removed by etching, resulting in formation of a diffraction grating 103. To this point, the means are similar to those described in the prior art.

Then, the active layer 102 and diffraction grating 103 in the region where the mirror is formed are removed by etching. If a resist pattern is formed by photolithography and etching is performed by using sulfuric acid and phosphoric acid, etc., a multilayer structure in the desired region can be removed. The post-removal structure becomes like that shown in FIG. 2A. Moreover, after removing the resist, crystal growth of a p-type InP clad layer 104 and a p+ contact layer 105 is carried out as shown in FIG. 2. Consequently, a p-i-n structure is formed to supply current to the active layer 102. Although a step almost the same as the active layer is formed at the boundary of the part between the removed part and the residual part of the active layer, the flatness other than the step part is excellent because no selective growth occurs and there is no problem to form the mirror. Or, prior to crystal growth of the p-type InP clad layer 104 and the p+ contact layer 105, butt joint re-growth of the semi-insulating InP may be carried out in the active layer 102.

After the p+ contact layer 105 in an unnecessary part is removed to become a structure like that shown in FIG. 2C by photolithography and wet-etching, dielectric masks 110 and 110′ are formed to leave a mesa wave guide region and a mirror formation region consisting of the active layer 102, the clad layer 104, and the diffraction grating layer 103. Silicon oxide and silicon nitride are preferable as a dielectric mask material. After the formation of the dielectric film over the all aspects of the wafer, a desired mask pattern like that shown in FIG. 2D can be formed by photolithography and etching. After the formation of the dielectric masks 110 and 110′, the exposed semiconductor part was removed by etching to reach the n-type InP buffer layer 112 below the active layer 102.

Next, a semi-insulating InP buried layer 106 is selectively re-grown, and a BH structure was formed wherein, among the four sides of the rectangular mesa type wave guide or the active layer, two longitudinal sides thereof were buried with the semi-insulating semiconductor. This example is shown in the C cross-section of FIG. 1 (FIG. 1C). In this embodiment, as shown in FIG. 2E, the wave guide region pattern 110 covering the mesa wave guide and the dielectric mask 110′ consisting of the mirror region pattern covering the mirror formation region are processed simultaneously. Thus, by using a mask shape wherein the mirror region pattern contacts one shorter side becoming an outgoing end of light among the sides with two kinds of length of the rectangular shape wave guide, the BH structure can be achieved wherein the side of the mesa wave guide is buried with the semi-insulating InP buried layer 106 while leaving the flat p-type InP clad layer 104 in the mirror formation region. However, Fe, Ru, and Os are preferable for an element to dope in the semi-insulating InP buried layer 106.

After the semi-insulating InP buried layer 106 is selectively grown, the dielectric masks 110 and 110′ are removed. Hereafter, the mirror 107 is formed by photolithography and etching on the extension line of the active layer with the angle reflecting the light from the active layer. According to this method, a flat mirror without misalignment can be manufactured with good yield because a smooth region without inclination by the selective growth effect can be left on the extension line of the light outgoing end of the mesa wave guide. As shown in the figure, the mirror is formed extending the p-type InP clad layer 104 and the n-type InP substrate 101 according to the depth. As a structural aspect of the present invention, the heights from the surface of the semiconductor substrate 101 to the upper surface of the active layer 102 become the p-type InP clad layer 104 at least in the mirror formation region.

Next, the laser p electrode 109 is formed over the p+ contact layer 105. As a material for the electrode, well-known Au and Ti are preferable. The electrode pattern can be formed by means such as a lift-off technique and ion-milling. In this case, in order to protect the semiconductor surface, a passivation film such as SiO₂, etc. is formed and a through hole is formed for contact between the p+ contact layer 105 and the laser p electrode 109, but they are omitted in this figure.

In consideration of the above aspects, a semiconductor optical element mentioned in this embodiment comprises a substrate, an active layer lying one direction over the substrate from which light exits using a side in the shorter direction among the four sides as an outgoing end, a buried layer provided over the substrate and covering the two side faces in the longitudinal direction among the four sides, a clad layer provided over the active layer and over the substrate existing on the extension line of the outgoing end of the active layer, and a mirror, which reflects light from the active layer, provided on the extension line of the active layer, wherein the aforementioned mirror is formed in the clad layer.

Moreover, a manufacturing method of a semiconductor optical element described in this embodiment comprises a first process forming a clad layer over an active layer, which is formed over a semiconductor substrate and has four sides, and over the above-mentioned semiconductor substrate, a second process forming a mask pattern over the clad layer, a third process etching the clad layer by using a mask pattern, a fourth process forming a buried layer over the semiconductor substrate surrounding the clad layer, and a fifth process forming a mirror at a position where light exiting the active layer is reflected, wherein the mask pattern is constructed of a wave guide region pattern formed over the active layer and a mirror region pattern to keep a region for forming the mirror and, more concretely, the wave guide region pattern is adjacent to the mirror region pattern.

According to these characteristics, a semiconductor optical element having a smooth mirror without misalignment can be formed with good yield because the flat region can be left as a mirror formation region.

Furthermore, as a modification of this embodiment, there is a structure in which a lens is provided at the position where light reflected by the mirror exits. In the case of this modification, the wafer is attached over the glass substrate and polished to be a desired thickness after the aforementioned surface process is completed.

Afterwards, as shown in FIG. 2H, the lens 108 is formed over the substrate surface opposite the face on which the mesa wave guide is formed. In this case, the lens 108 is formed at the position where the light exited from the waveguide and reflected by the mirror exits to outside of the substrate. Then, antireflection coating to suppress the reflection at the lens part and formation of n-type electrode over the n-InP substrate 101 were performed, but they are omitted in this figure. According to the above-mentioned procedure, a laser having a BH type structure can be manufactured wherein the main signal light exits from the mirror in the direction of the substrate surface.

Continuing, the operation of this element is briefly described. Current flows in the active layer 102 by grounding the n electrode and applying forward bias to the laser p electrode 109. Light generated by current injection is amplified and, while feedback-is reflected in the in-plane direction of the substrate by the diffraction grating 103, reaches laser oscillation. The laser oscillation beam is emitted from the tip of the mesa wave guide and returned to the substrate direction by the mirror 107, and focused by the lens 108. The focused light can be connected to an optical fiber highly effectively. Moreover, high-speed optical modulation is possible by adding a modulating electric signal around an appropriate bias point.

In the embodiment, an n-type InP substrate was used as a semiconductor substrate, but a p-type InP may also be used.

In this case, one only has to make the clad layer and the contact layer over the active layer n-type. Moreover, the purpose of the present invention can be achieved if there is no lens 108.

This embodiment shows an example in which the present invention is applied to a semiconductor laser element but, as a consequence, it is possible to apply the invention to a semiconductor photo-detector. In this case, it can be considered that a wave guide core layer is used as a substitute for the active layer 102. Thus, in the case of a photo-detector, the semiconductor optical element described in this embodiment comprises a semiconductor substrate, a core layer and a clad layer formed over the substrate, a wave guide lying in one direction in which light enters or exits using a side face of the shorter side among the four sides as an incident and exit end, a mirror formed on the extension line of the wave guide and at the position where light from the wave guide is reflected, and a buried layer formed over the substrate covering at least two sides in the longitudinal direction among the four sides of the wave guide, wherein the clad layer is further formed over the semiconductor substrate on the extension line of the incident and outgoing end of the wave guide and the mirror is formed in the clad layer.

According to the characteristics, the mirror can be formed in a flat region without the influence of selective growth, and a photo-detector having a smooth mirror without misalignment can be fabricated with good yield.

### Second Embodiment

The embodiment of a semiconductor optical element to which the present invention is applied will be described by using FIGS. 1 to 4. In the embodiment, there is a difference that a mask pattern with a different shape from the first embodiment is used, but other processes, specifically from FIGS. 2A to 2C and FIGS. 2F to 2H are similar to those of the first embodiment.

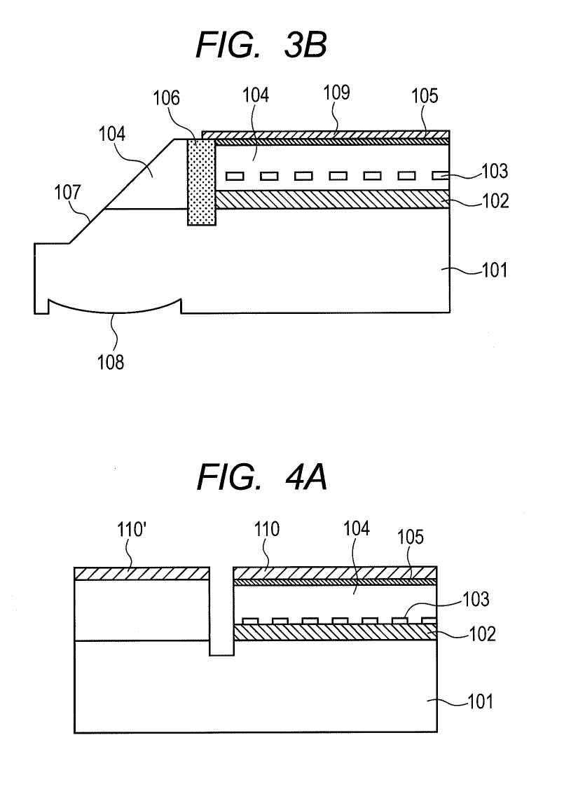

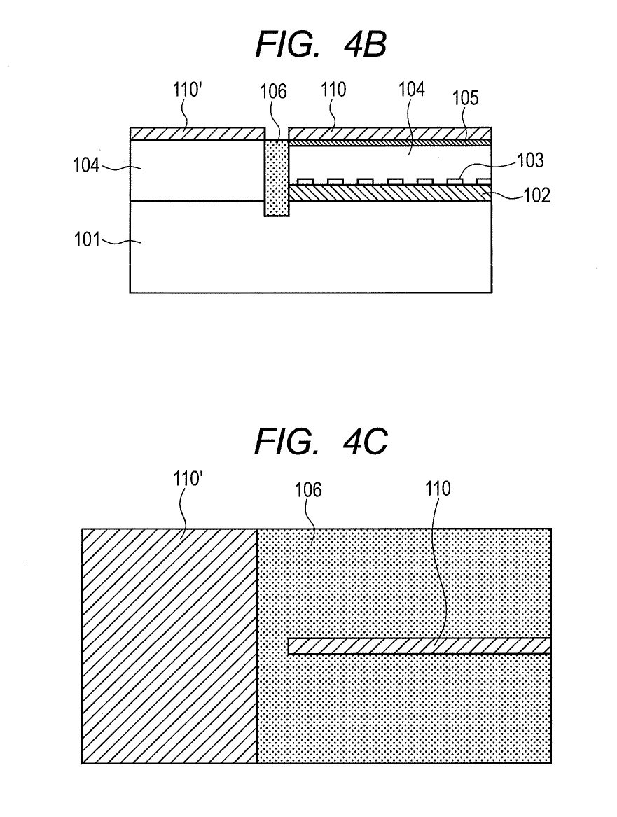

After the processes up to FIG. 2B of the first embodiment are completed, an unnecessary part of the p+ contact layer 105 is removed by photolithography and wet-etching, and the dielectric mask (mirror region pattern) leaving the mirror formation region and the dielectric masks (wave guide region pattern) 110 and 110′ for forming the mesa wave guide consisting of the active layer, the clad layer, and the diffraction grating layer are formed as shown in FIG. 4C. Silicon oxide and silicon nitride are preferable as the dielectric mask material. After the formation of the dielectric film over the all aspects of the wafer, a desired mask pattern can be formed by photolithography and etching. After the formation of the dielectric mask 110 and dielectric mask 110′, the exposed semiconductor part was removed to reach the n-type InP buffer layer 112 below the active layer 102. Then, a BH structure was formed as the same as in the first embodiment (FIG. 1C). Since the C cross-section of FIG. 3A is the same as the first embodiment (FIG. 1C), the drawing was omitted.

In this embodiment, as shown in FIG. 4C, the dielectric mask 110 covering the mesa wave guide is formed apart from the dielectric mask 110′ covering the mirror formation region. A BH structure can be achieved by using a mask with such a shape, wherein the p-type InP clad layer 104 with excellent flatness is kept in the mirror formation region because of no selective growth and both sides and the outgoing end of the mesa wave guide are buried with the semi-insulating InP buried layer 106 (FIGS. 3A and 3B). Thereby, leakage current can be reduced at not only the side of the wave guide but also the tip, and a further low current drive becomes possible. Fe, Ru, and Os, etc. are preferable for an element to dope in the semi-insulating InP buried layer 106.

The processes after this are similar to those of the first embodiment (FIGS. 2F to 2H).

Subsequently, operation of this element will be briefly described.

Current flows in the active layer 102 by grounding the n electrode and applying a forward bias to the laser p electrode 109. Light generated by current injection is amplified and, while feedback is reflected in the in-plane direction of the substrate by the diffraction grating 103, reaches laser oscillation. The laser oscillation beam is emitted from the tip of the mesa wave guide and returned to the substrate direction by the mirror 107, and focused by the lens 108. The focused light can be connected to an optical fiber with high efficiency. Moreover, high-speed optical modulation is possible by adding a modulating electric signal around an appropriate bias point. Moreover, in addition to the effect of first embodiment, the effect of reduction of the leakage current at the light outgoing end of the mesa wave guide can be obtained.

In the embodiment, an n-type InP substrate was used as a substrate, but a p-type InP may be used. In this case, one only has to make the clad layer and the contact layer over the active layer n-type. Moreover, the lens 108 is not always necessary.

### Third Embodiment

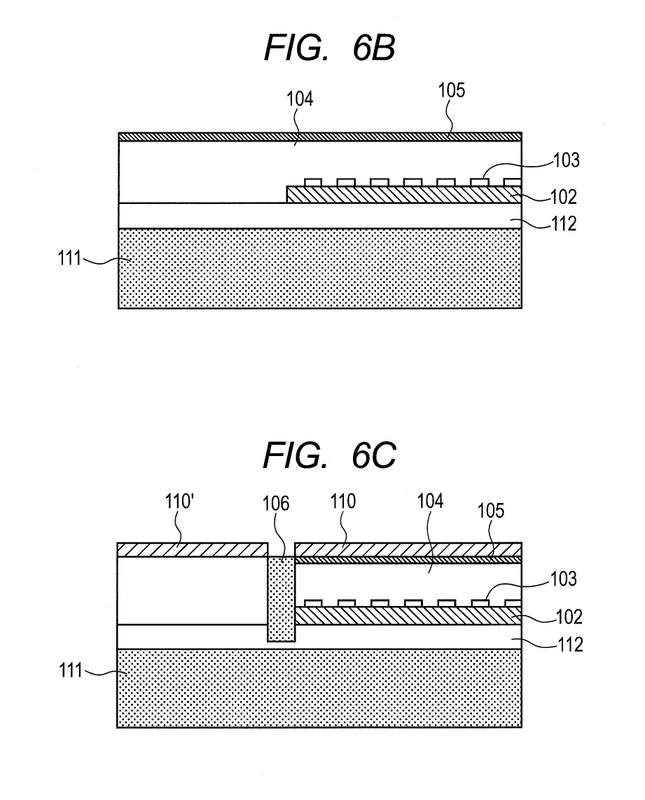

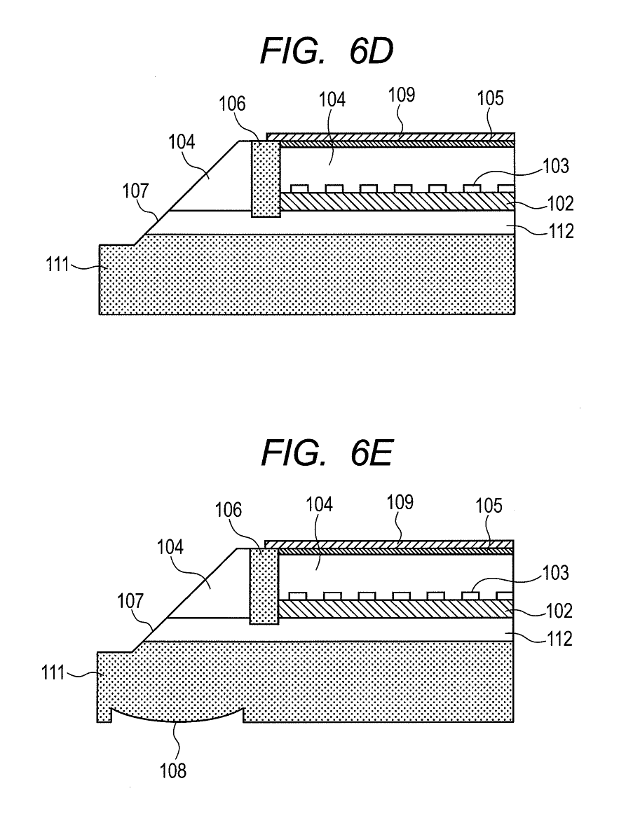

An embodiment of a semiconductor optical element to which the present invention is applied will be described by using FIGS. 1 to 6. In this embodiment, a single-sided electrode take-out structure is adopted wherein a semiconductor optical element is formed by using a semi-insulating InP substrate 111 and both p and n electrodes are provided over one side of the semiconductor optical element in contrast to the second embodiment.

First, crystal growth of the n-type InP buffer layer 112, the active layer 102, and the diffraction grating supply layer 103′ are carried out over the semi-insulating InP substrate ill by using a Metal-organic Vapor Phase Epitaxy (MOVPE) etc. the same as in the first and second embodiments. Hereinafter, because the process up to forming the mirror is the same as that of the second embodiment, they are omitted.

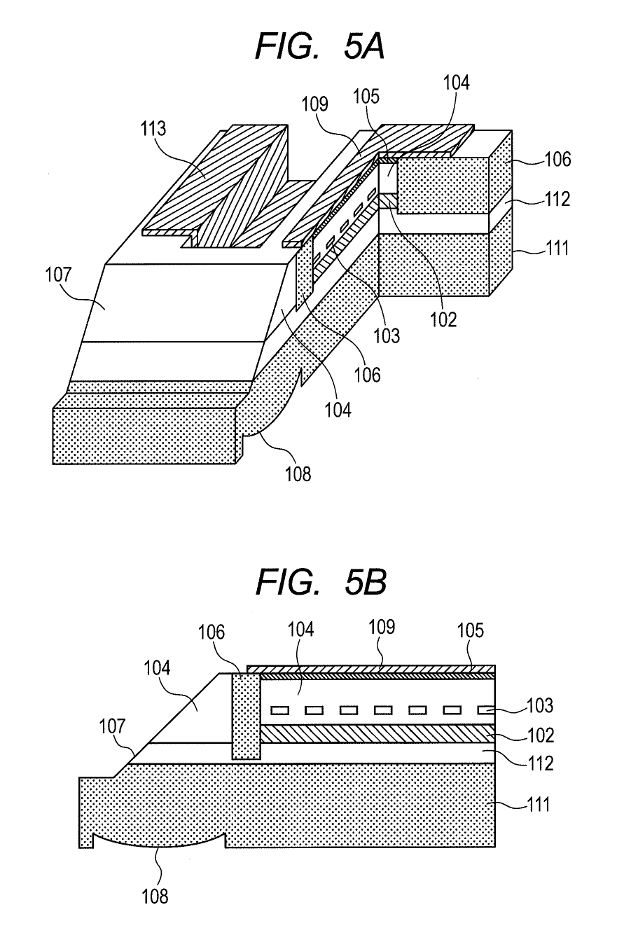

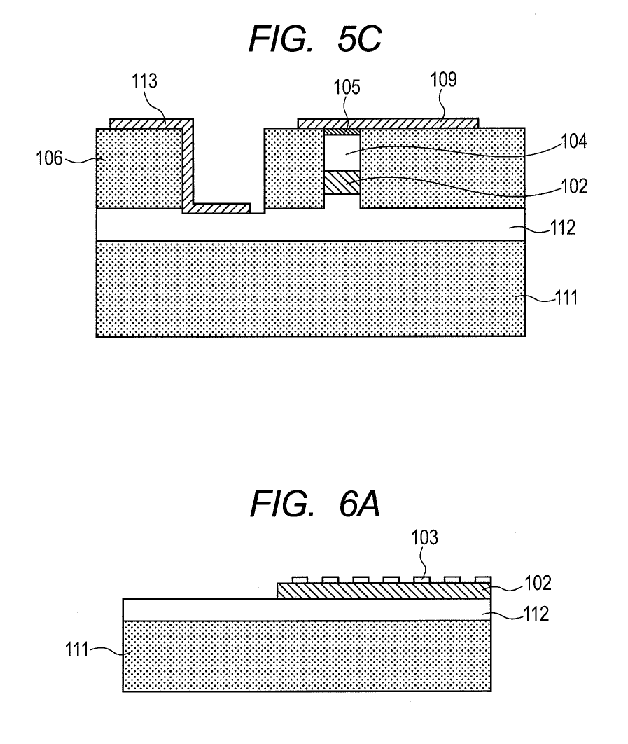

Next, the laser p electrode 109 is formed over the p+ contact layer 105. Moreover, the laser n electrode 113 is also formed over the surface of the wafer. As shown in FIG. 5C, a semi-insulating InP buried layer 106 is removed by etching to reach the n-type InP buffer layer 112. As a material for the electrode, well-known Au and Ti are preferable. The electrode pattern can be formed by means such as a lift-off technique and ion-milling. In this case, in order to protect the semiconductor surface, a passivation film such as SiO₂, etc. is formed and a through hole is formed for contact between respective contact-parts of p-type and n-type and the electrode, but they are omitted in this figure.

The wafer is attached over the glass substrate and polished to be a desired thickness after the surface process is completed the same as in the second embodiment. Afterwards, the lens 108 is formed over the substrate surface on the other side of the face on which the mesa wave guide is formed. In this case, the lens 108 is formed at the position where the light exits from the wave guide and, reflected by the mirror, exits the substrate. Then, an antireflection coating for suppressing reflection at the lens part was performed, but it is omitted in this figure. According to the above-mentioned procedure, a laser having a BH type structure can be manufactured wherein the main signal light exits from the mirror in the direction of the substrate surface.

Continuing on, the operation of this element is briefly described. Current flows in the laser active layer 102 by grounding the laser n electrode 113 and applying a forward bias to the laser p electrode 109. Light generated by current injection is amplified and, while feedback-is reflected in the in-plane direction of the substrate by the diffraction grating 103, reaches laser oscillation. The laser oscillation beam is emitted from the tip of the mesa and returned to the substrate direction by the taper mirror 107, and focused by the lens 108. The focused light can be connected to an optical fiber highly effectively. Moreover, high-speed optical modulation is possible by adding a modulating electrical signal around an appropriate bias point. Moreover, in addition to the effect of the second embodiment, a laser element preferable for mounting a flip chip can be achieved by forming both p-type and n-type electrodes over the wafer surface as in this embodiment.

A semi-insulating InP substrate was used for the substrate in this embodiment, but a conductive substrate may be preferable. Moreover, the polarity of the InP buffer layer on the semi-insulating InP substrate was made n-type, but p-type may be preferable. In this case, one only has to make the clad layer and the contact layer over the laser active layer n-type. Moreover, the lens 108 is not always necessary. Fe, Ru, and Os, etc. are preferable for an element to dope in the semi-insulating InP substrate.

### Fourth Embodiment

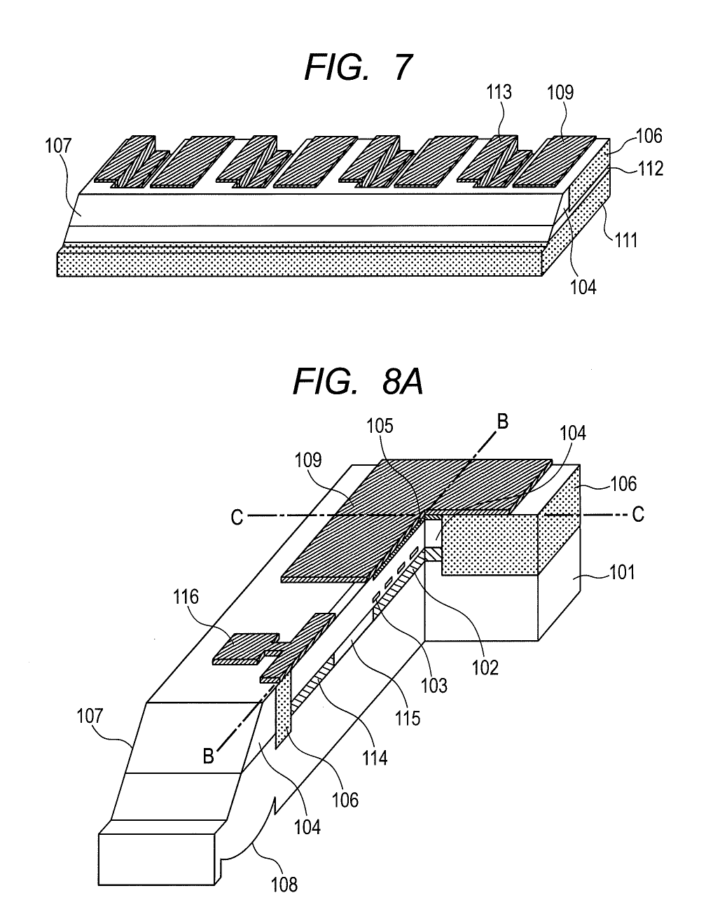

An embodiment of a semiconductor optical element to which the present invention is applied will be described by using FIG. 7.

This embodiment is one in which the element described in the third embodiment is made to be an array shape. Since the manufacturing method of the element is the same as the third embodiment, it is omitted. Thus, the optical module can be made smaller by making the element in an array shape. Moreover, in this embodiment, the mirror 107 is formed continuously without spacing between adjacent elements, but it may have a shape which has a smaller width than each element end and may be divided between adjacent elements. Moreover, although it is omitted in this embodiment, a separation groove which penetrates the n-type InP buffer layer 112 in the direction parallel to the optical axis reaches the semi-insulating InP substrate 111 in order to reinforce the electrical isolation between adjacent elements.

### Fifth Embodiment

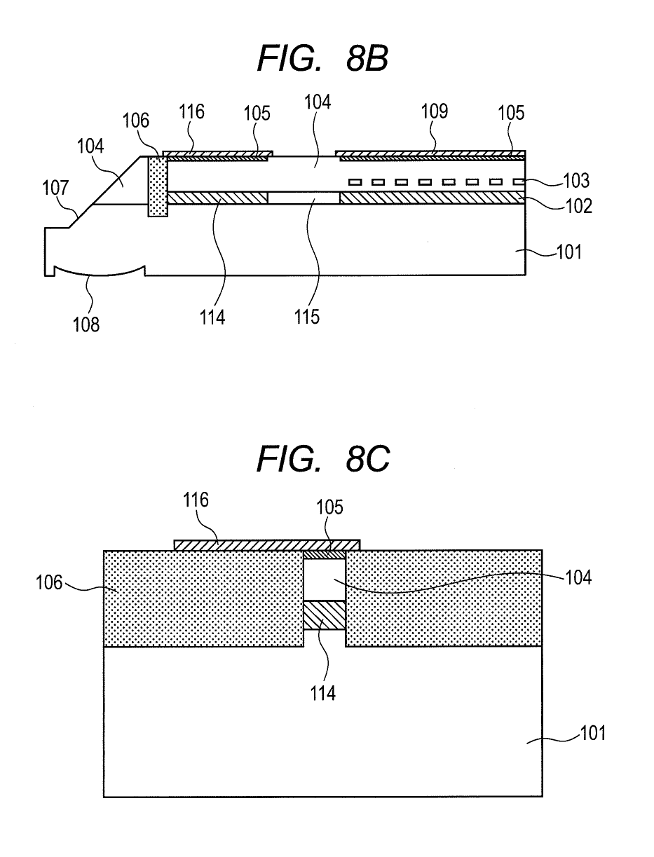

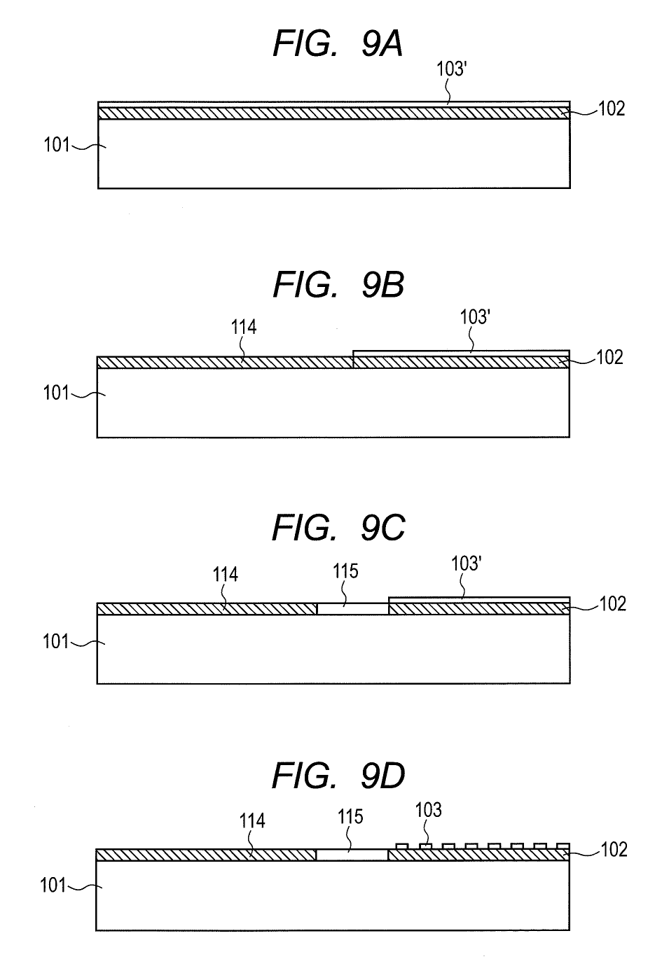

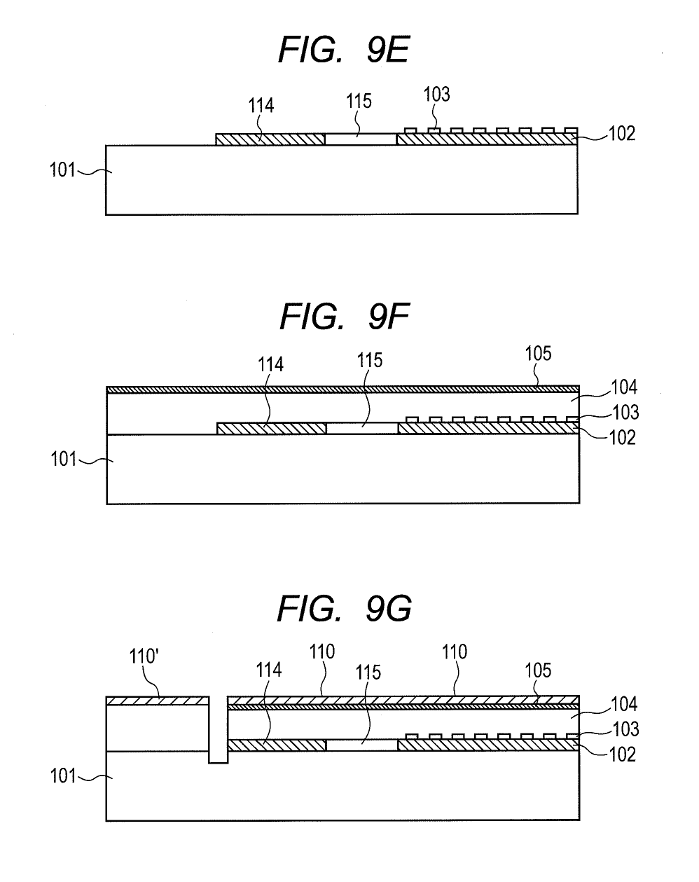

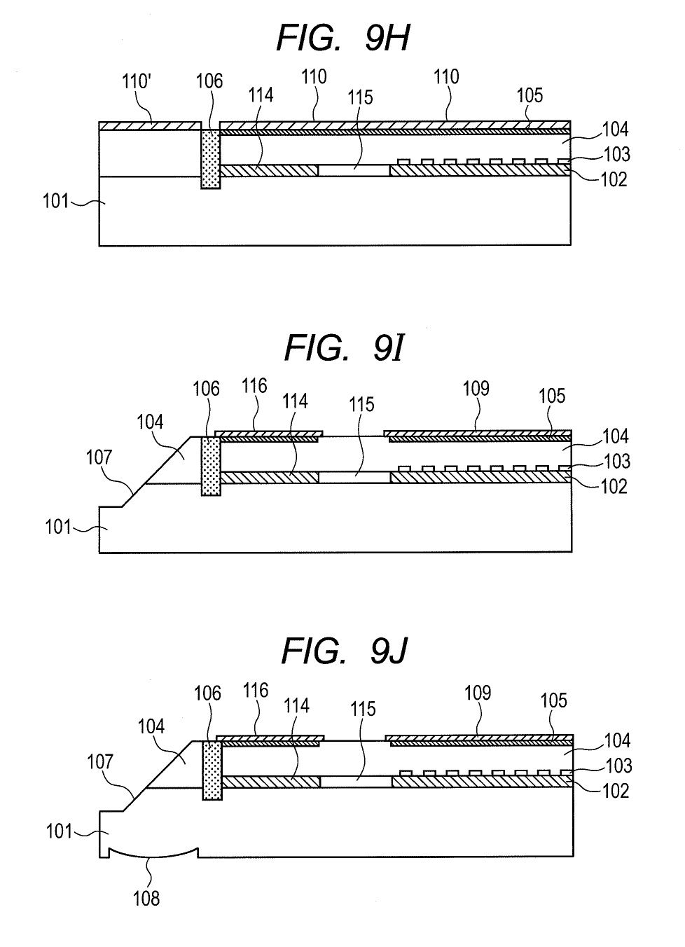

An embodiment of a semiconductor optical element to which the present invention is applied will be described by using FIGS. 8 and 9. This embodiment is one in which an EA modulator is accumulated based on the structure of the second invention.

First, crystal growth of the active layer 102 and the diffraction grating supply layer 103′ are carried out over the n-type InP substrate 101 by using Metal-organic Vapor Phase Epitaxy (MOVPE) etc. the same as the first and second embodiments (FIG. 9A). Then, the active layer 102 and the diffraction grating supply layer 103′ are etched to reach the surface of the n-type InP substrate 101 leaving a desired length.

Next, butt joint growth of an optical absorption layer 114 consisting of an InGaAlAs system quantum well is carried out to become an electro-absorption (EA) modulator (FIG. 9B). The quantum well and barrier layer are alternately stacked to be about six to ten layers, resulting in forming an optical confinement structure suitable for photo-absorption. It is preferable that the composition wavelength of the quantum well be adjusted to make the absorption peak wavelength of the photo-absorption layer several tens of milli-electron-volts by energy conversion higher than the emission wavelength of the DFB laser. Then, the EA modulator and the semiconductor laser part are etched to reach the surface of the n-type InP substrate 101 leaving a desired length. At this time, etching is simultaneously performed between the electro-absorption modulator and the semiconductor laser part and between the light outgoing end and the electro-absorption modulator. Next, an optical wave guide layer (core layer) 115 consisting of an InGaAsP system or InGaAlAs system is formed between the EA modulator and the semiconductor laser part (FIG. 9C). For example, an InGaAsP system bulk layer with a thickness of about 300 nm and a composition wavelength of 1150 nm is preferable for a detailed structure of the optical wave guide layer (core layer) 115. A resist pattern having a desired pitch is formed over the diffraction grating supply layer 103′ by using a means such as interference exposure and electron beam exposure, and unnecessary parts are removed, resulting in forming the diffraction grating 103 (FIG. 9D).

Then the photo-absorption layer 114 in the region where the mirror is formed are continuously etching-removed the same as other embodiments (FIG. 9E). Crystal growth of the p-type InP clad layer 104 and the p+ contact layer 105 is carried out after removing the resist (FIG. 9F). Thus, p-i-n structure is formed to apply a reverse bias to the photo-absorption layer 114 and current to the active layer 102.

Hereinafter, the same as the second embodiment, after unnecessary parts of the p+ contact layer 105 are removed by photolithography and wet-etching, a dielectric mask (wave guide region pattern) 110 and dielectric mask (mirror region pattern) 110′ are formed in order to leave the mesa wave guide and the mirror formation region. Silicon oxide and silicon nitride are preferable as the dielectric mask material. After the formation of the dielectric film over the all aspects of the wafer, a desired mask pattern can be formed by photolithography and etching. After the formation of the dielectric mask 110 and dielectric mask 110′, the exposed semiconductor part was removed to reach the photo-absorption layer 114, the active layer 102, and the n-type InP substrate 101 below the optical wave guide layer (core layer) 115 (FIG. 9G). Next, a semi-insulating InP buried layer 106 is selectively re-grown, and a BH structure was formed wherein both sides of the mesa wave guide and the outgoing end are buried with the semi-insulating semiconductor (FIGS. 8A and 8C).

In this embodiment, the dielectric mask 110 covering the mesa wave guide region is formed separated from the dielectric mask (mirror region pattern) 110′ covering the mirror formation region. A BH structure can be achieved by using a mask with such a shape, wherein the p-type InP clad layer 104 with excellent flatness is kept in the mirror formation region because of no selective growth and both sides in the longitudinal direction of the mesa wave guide and the outgoing end are buried with the semi-insulating InP buried layer 106. Thereby, the leakage current can be reduced at not only both sides of the mesa wave guide but also the tip, consequently a low current drive becomes possible. Fe, Ru, and Os, etc. are preferable for an element to dope in the semi-insulating InP buried layer 106.

After the semi-insulating InP buried layer 106 is selectively grown, the dielectric mask 110 and the dielectric mask 110′ are removed. Then, the mirror 107 is formed by photolithography and etching (FIG. 9I). According to this method, a smooth mirror without misalignment can be manufactured with good yield because a flat region without inclination by the selective growth can be left on the extension line of the light outgoing end of the mesa wave guide. As shown in the figure, the mirror is formed extending the p-type InP clad layer 104 and the n-type InP substrate 101 depending on depth. As a structural aspect of the present invention, the heights from surface of the semiconductor substrate 101 to the upper surface of the active layer 102 become the p-type InP clad layer 104 at least in the mirror formation areas.

Next, the EA modulator p electrode 116 and the laser p electrode 109 are formed over the p+ contact layers 105 of the EA modulator and DFB laser part, respectively. As a material for the electrode, well-known Au and Ti are preferable. The electrode pattern can be formed by means such as a lift-off technique and ion-milling. In this case, in order to protect the semiconductor surface, a passivation film such as SiO₂, etc. is formed and a through hole is formed for contact between the p+ contact layer 105, the EA modulator p electrode 116, and the laser p electrode 109, but they are omitted in this figure.

The wafer is attached over the glass substrate and polished to be a desired thickness after the surface process is completed. Then, an antireflection coating for suppressing reflection at the lens part and formation of n-type electrode over the n-InP substrate 101 were performed, but these are omitted in this figure. According to the above-mentioned procedure, an EA modulator integrated laser with a BH type structure can be manufactured wherein the main signal light exits from the mirror in the direction of the substrate surface.

Continuing on, the operation of this element is briefly described. Current flows in the active layer 102 by grounding n electrode and applying a forward bias to the laser p electrode 109. Light generated by current injection is amplified and, while feedback is reflected in the in-plane direction of the substrate by the diffraction grating 103, reaches laser oscillation. The laser oscillation beam enters the photo-absorption layer 114 by propagating through the optical wave guide core layer 115. Herein, the absorption edge wavelength of the photo-absorption layer shifts to the low energy side by applying a reverse bias to the EA modulator p electrode 116, resulting in absorbing the laser beam. Penetration and absorption of the laser beam are switched by applying a high-speed voltage signal and high-speed modulation becomes possible. The light is emitted from the tip of mesa of the EA modulator and returned to the substrate direction by the mirror 107, and focused by the lens 108. The focused light can be connected to an optical fiber highly effectively.

A p-type InP substrate was used in this embodiment, but a p-type InP substrate may be preferable. In this case, one only has to make the clad layer and the contact layer above it n-type. Moreover, the lens 108 is not always necessary. Moreover, the optical wave guide core layer 115 is not always necessary. According the description of the first to fourth embodiments, the case of using the semiconductor substrate and the case of an array shape may be easily considered. Moreover, as a substitute for the EA modulator, a Mach-Zehnder modulator using phase modulation may be added. Furthermore, a manufacturing method of the element may be easily considered when the DFB laser part is substituted for other optical function structures such as SOA, etc.

### Sixth Embodiment

This embodiment shows an example of an optical module in which a semiconductor optical element of the present invention is applied.

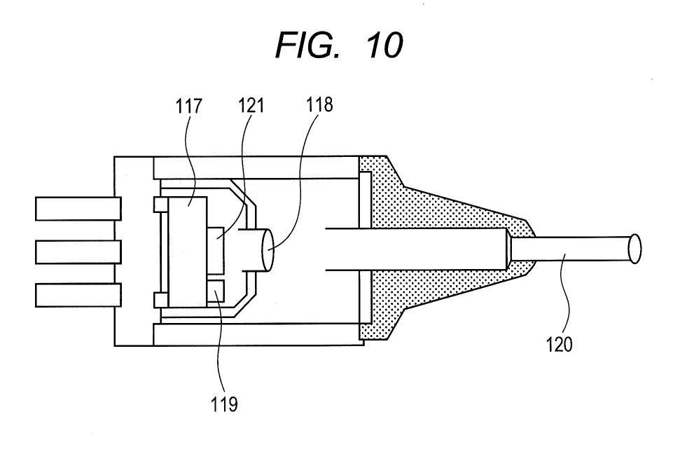

There is a structural drawing of an optical transmitter module as shown in FIG. 10, wherein the optical lens 118, the driving circuit 119 for driving the semiconductor laser element and the optical fiber 120 are integrated after the semiconductor optical element 121 of the first embodiment is mounted over the heat-sink 117. The threshold current was 5 mA and the efficiency of the laser was 0.3 w/A at room temperature and in a condition of continuity. The optical coupling efficiency with the lens is excellent by reflecting the circular narrow exit beam of the present invention, and a highest module optical output of 5 mW or more was able to be achieved. Moreover, mounting is easy by reflecting the effect of the present invention, and a low-cost optical transmission module can be manufactured.

What is claimed is:

1. A semiconductor optical element comprising:
a substrate;
an active layer lying in one direction over the substrate from which light exits using a side in the shorter direction among the four sides as an exit end;
a buried layer provided over the substrate and covering the two sides in the longitudinal direction among the four sides;
a clad layer provided over the active layer and over the substrate existing on the extension line of the outgoing end of the active layer; and
a mirror which reflects light from the active layer, provided on the extension line of the active layer,
wherein the mirror is formed in the clad layer.

2. The semiconductor optical element according to claim 1, wherein the buried layer further covers the outgoing end of the active layer.

3. The semiconductor optical element according to claim 1, wherein a diffraction grating is provided between a part located over the active layer in the clad layer and the active layer.

4. The semiconductor optical element according to claim 1, further comprising:
a lens at a position of the substrate opposite the face where the active layer is provided and outgoing light is reflected by the mirror,
wherein the mirror is formed at an angle to reflect light exiting from the active layer in the direction of the side where the lens is provided.

5. The semiconductor optical element according to claim 1, wherein an EA modulator is provided between the active layer and the mirror.

6. An optical module comprising:
a semiconductor optical element according to claim 1; and
a driving circuit to drive the semiconductor optical element.

7. A semiconductor optical element comprising:
a substrate;
a core layer and a clad layer formed over the substrate;
a wave guide lying in one direction wherein light enters and exits from a side in the shorter direction among the four sides as an outgoing edge face;
a mirror formed at the position which reflects light from the wave guide on the extension line of the wave guide; and
a buried layer formed over the substrate and covering at least two sides in the longitudinal direction among the four sides of the wave guide,
wherein the clad layer is formed over the semiconductor substrate on the extension line of the incident and outgoing end of the wave guide and the mirror is formed in the clad layer.

8. The semiconductor optical element according to claim 7, wherein the buried layer covers the incident and outgoing end of the active layer.

9. The semiconductor optical element according to claim 7, further comprising:
a lens at a position of the substrate opposite the face where the active layer is provided and exiting light reflected by the mirror,
wherein the mirror is formed at an angle to reflect light exiting from the active layer in the direction of the side where the lens is provided.

10. A manufacturing method of a semiconductor optical element comprising:
a first process forming a clad layer over an active layer, which is formed over a semiconductor substrate and has four sides, and over the semiconductor substrate;
a second process forming a mask pattern over the clad layer;
a third process etching the clad layer by using the mask pattern;
a fourth process forming a buried layer over the semiconductor substrate surrounding the clad layer;
a fifth process forming a mirror at a position where light exiting from the active layer is reflected,
wherein the mask pattern is constructed of a wave guide region pattern formed over the active layer and a mirror region pattern to keep a region for forming the mirror.

11. The manufacturing method of a semiconductor optical element according to claim 10, wherein the wave guide region pattern is adjacent to the mirror region pattern.

12. The manufacturing method of a semiconductor optical element according to claim 10, wherein the wave guide region pattern is separated from the mirror region pattern.
